(19) United States
(12) Patent Application Publication
(10) Pub. No.: US 2023/0114404 A1
(43) Pub. Date: Apr. 13, 2023

(54) EMBEDDED TRACE SUBSTRATE (ETS) WITH EMBEDDED METAL TRACES HAVING MULTIPLE THICKNESS FOR INTEGRATED CIRCUIT (IC) PACKAGE HEIGHT CONTROL

(71) Applicant: QUALCOMM Incorporated, San Diego, CA (US)

(72) Inventors: Seongryul Choi, Seongnam (KR); Kuiwon Kang, San Diego, CA (US); Joan Rey Villarba Buot, Escondido, CA (US)

(21) Appl. No.: 17/822,589

(22) Filed: Aug. 26, 2022

Related U.S. Application Data
(60) Provisional application No. 63/250,865, filed on Sep. 30, 2021.

(51) Int. Cl. H01L 23/538; H01L 25/10; H01L 23/00; H01L 21/48; H01L 23/498

(52) U.S. Cl. CPC H01L 23/5386; H01L 21/486; H01L 21/4853; H01L 21/4857; H01L 23/5385; H01L 23/49816; H01L 23/49822; H01L 23/49833; H01L 23/49838; H01L 24/16; H01L 24/32; H01L 24/73; H01L 25/105; H01L 2224/16225; H01L 2224/32225; H01L 2224/73204; H01L 2225/1023; H01L 2225/1035; H01L 2225/1041; H01L 2225/1058; H01L 2225/1088; H01L 2225/1094; H01L 2924/1436; H01L 2924/3511

(57) ABSTRACT

Embedded trace substrate (ETS) with embedded metal traces having multiple thicknesses for integrated circuit (IC) package height control, and related IC packages and fabrication methods. The IC package includes a die that is coupled to a package substrate to provide signal routing paths to the die. The IC package also includes an ETS that includes metal traces embedded in an insulating layer(s) to provide connections for signal routing paths for the IC package. To control (such as to reduce) the height of the IC package, the embedded metal traces embedded in an insulating layer in the ETS are provided to have multiple thicknesses (i.e., heights) in a vertical direction. The embedded metal traces in the ETS whose thicknesses affect the overall height of the IC package by being coupled to interconnects external to the ETS in the vertical direction, can be reduced in thickness to control IC package height.

### PRIORITY APPLICATION

The present application claims priority to U.S. Provisional Pat. Application Serial No. 63/250,865, filed Sep. 30, 2021 and entitled “EMBEDDED TRACE SUBSTRATE (ETS) WITH EMBEDDED METAL TRACES HAVING MULTIPLE THICKNESS FOR INTEGRATED CIRCUIT (IC) PACKAGE HEIGHT CONTROL,” which is incorporated herein by reference in its entirety.

### BACKGROUND

### I. Field of the Disclosure

The field of the disclosure relates to integrated circuit (IC) packages, and more particularly to design and manufacture of package substrates that support signal routing to a semiconductor die(s) in the IC package.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include metal interconnects (e.g., metal traces, metal lines) with vertical interconnect accesses (vias) coupling the metal interconnects together between adjacent metallization layers to provide electrical interfaces between the die(s). The die(s) is electrically interfaced to metal interconnects exposed in a top or outer layer of the package substrate to electrically couple the die(s) to the metal interconnects of the package substrate. The package substrate includes an outer metallization layer coupled to external metal interconnects (e.g., solder bumps) to provide an external interface between the die(s) in the IC package for mounting the IC package on a circuit board to interface the die(s) with other circuitry. The package substrate may include an embedded trace substrate (ETS) (or include a thin ETS metallization layer) adjacent to the die to facilitate higher density bump/solder joints for coupling the die(s) to the package substrate.

Some IC packages are known as “hybrid” IC packages. Hybrid IC packages include multiple dies for different purposes or applications. For example, a hybrid IC package may include an application die, such as a communications modem or processor (including a system). The hybrid IC package could also include one or more memory dies to provide memory to support data storage and access by the application die. The multiple dies can be provided in their own respective die packages that are stacked on top of each other within an overall IC package to reduce the cross-sectional area of the package, known as a stacked-die IC package. In a stacked-die IC package, a first die package is provided that includes a first, bottom die supported by a first, bottom substrate. First die interconnects of the first die are coupled to metal interconnects in the first substrate that are connected to external interconnects (e.g., solder bumps) and other interface interconnects to provide an electrical signal interface to the first die. A second die package that includes a second die is stacked above the first die package in the stacked-die IC package. The second die is electrically coupled through second die interconnects to metal interconnects in a second substrate of the second die package. To provide support and interconnectivity between the second die package and the first die package for die-to-die (D2D) connections as well as between the second die and the external interconnects, the first die package can include an interposer substrate that is disposed adj acent to the first die between the first die package and the second die package. The second die package is coupled to the interposer substrate to provide a connection interface between the first die package and the second die package for D2D and external connections.

### SUMMARY OF THE DISCLOSURE

Aspects disclosed herein include an embedded trace substrate (ETS) with embedded metal traces having multiple thickness for integrated circuit (IC) package height control. Related IC packages and IC package fabrication methods are also disclosed. The IC package includes a semiconductor die (“die”) that is coupled to a package substrate to provide signal routing paths to the die. The IC package also includes an ETS that includes metal traces embedded in an insulating layer(s) to provide connections for signal routing paths for the IC package. The package substrate coupled to the die can include an ETS. An interposer substrate that is included in a stacked-die IC package to provide an electrical interface between stacked die packages could also include an ETS. An ETS can be disposed on an outer side of a substrate in the IC package to facilitate interconnections between substrate and external interconnects (e.g., ball grid arrays (BGAs)) providing an external interface to the IC package. An ETS can also be disposed on an inner side of an interposer substrate in an IC package to facilitate interconnections between the interposer substrate and a package substrate. In either configuration, the thickness (i.e., height) of the embedded metal traces in the ETS contributes to the overall height of the IC package. In this regard, in exemplary aspects disclosed herein, to control (such as to reduce) the height of the IC package, the embedded metal traces embedded in an insulating layer in the ETS are provided to have multiple thicknesses (i.e., heights) in a vertical direction. The embedded metal traces in the ETS whose thicknesses affect the overall height of the IC package by being coupled to interconnects external to the ETS in the vertical direction, can be reduced in thickness to control (such as to reduce) the IC package height. In this regard, some embedded metal traces in the ETS have a reduced thickness as compared to certain other embedded metal traces in the ETS. As an example, the embedded metal traces desired to be reduced in thickness could be selectively etched during the fabrication of the IC package. Thus, reducing the height of the embedded metal traces in an ETS whose thicknesses affect the height of its IC package reduces the overall height of the IC package.

Further, in other exemplary aspects, embedded metal traces in the ETS can be reduced in height by recessing the embedded metal traces below an outer surface of an insulating layer in the ETS in which metal traces were formed. This allows the insulating layer in the ETS to function as a mask, because the recessed embedded metal traces form openings in the insulating layer above the embedded metal traces. These openings in the insulating layer form channels that can be used in fabrication to align the formation of external interconnects (e.g., ball grid array (BGA) interconnects) in the openings to be coupled to the recessed embedded metal traces to form interconnections. In this manner, a solder resist layer is not required to be provided and disposed on the outer surface of the insulating layer to be used as a mask for the formation of external interconnects coupled to respective embedded metal traces in the ETS. Avoiding the need for use of a solder resist mask can also reduce the overall height of the IC package, because a solder resist mask, when employed, is a layer that remains resident in an IC package after fabrication. To further avoid the need for a solder resist mask, the external interconnects can be bonded to embedded metal traces in the ETS without the use of solder (e.g., through direct metal bonding) such that the ETS is solderless. Also, in another example, eliminating the use of a solder resist mask in the IC package can reduce coefficient of thermal expansion (CTE) mismatch between the ETS and the external interconnects. The CTE of the embedded metal traces is relatively low as compared to the CTE of the solder resist layer. A solder resist layer may not be able to absorb the difference in thermal expansion to embedded metal traces due to heat cycle during fabrication of the IC package. The elimination of a solder resist mask can also reduce the overall CTE of the IC package to reduce warpage.

In this regard, in one exemplary aspect, an IC package is provided. The IC package comprises a substrate comprising a first metallization layer. The first metallization layer comprises an insulating layer comprising a first surface and a metal layer comprising a plurality of metal traces embedded in the insulating layer. One or more first metal traces among the plurality of metal traces each having a first thickness in a vertical direction. One or more second metal traces among the plurality of metal traces have a second thickness less than the first thickness in the vertical direction.

In another exemplary aspect, a method of fabricating a substrate for an IC package is provided. The method comprises forming a substrate comprising forming a first metallization layer. Forming the first metallization layer comprises forming an insulating layer comprising a first surface and forming a metal layer comprising a plurality of metal traces in the insulating layer. Forming a plurality of metal traces in the insulating layer comprises embedding one or more first metal traces among a plurality of metal traces in the insulating layer having a first thickness in a vertical direction. Forming a plurality of metal traces in the insulating layer also comprises embedding one or more second metal traces among the plurality of metal traces having a second thickness less than the first thickness in the vertical direction.

### BRIEF DESCRIPTION OF THE FIGURES

FIG. 1 is a side view of an exemplary stacked-die integrated circuit (IC) package that includes a second die package stacked on the first die package, and wherein the IC package includes at least one substrate that includes an embedded trace substrate (ETS) with embedded metal traces of multiple thicknesses for IC package height control (e.g., height reduction);

FIGS. 2A and 2B are detailed side views of the first die package that can be included in the first die package in the IC package in FIG. 1;

FIG. 3 is a side view of an exemplary IC package that includes an interposer substrate with an ETS with embedded metal traces that are connected to external interconnects having a reduced thickness for IC package height control (e.g., height reduction), wherein the ETS is disposed on an inner side of the interposer substrate;

FIG. 4 is a side of another exemplary IC package that includes an interposer substrate with an ETS with embedded metal traces that are connected to external interconnects, having a reduced thickness for IC package height control (e.g., height reduction), wherein the ETS is disposed on an outer side of the interposer substrate;

FIG. 5 is a side of another exemplary IC package that includes a package substrate with an ETS with embedded metal traces that are connected to external interconnects, having a reduced thickness for IC package height control (e.g., height reduction), wherein the ETS is disposed on an outer side of the package substrate;

FIG. 6 is a flowchart illustrating an exemplary fabrication process of fabricating an IC package that includes at least one substrate that includes an ETS with embedded metal traces of multiple thicknesses for IC package height control (e.g., height reduction), including but not limited to the IC packages and related substrates in FIGS. 1 and 3-5;

FIGS. 7A-7C is a flowchart illustrating another exemplary fabrication process of fabricating an IC package that includes at least one substrate that includes an ETS with embedded metal traces of multiple thicknesses for IC package height control (e.g., height reduction), including but not limited to the IC packages and related substrates in FIGS. 1 and 3-5;

FIGS. 8A-8F are exemplary fabrication stages during fabrication of an IC package according to the fabrication process in FIGS. 7A-7C;

FIG. 9 is a block diagram of an exemplary processor-based system that can include components that can include an IC package that includes at least one substrate that includes an ETS with embedded metal traces of multiple thicknesses for IC package height control (e.g., height reduction), including but not limited to the IC packages and related substrates in FIGS. 1 and 3-5 and according to any of the exemplary fabrication processes in FIGS. 6-8F; and

FIG. 10 is a block diagram of an exemplary wireless communications device that includes radio-frequency (RF) components that can include an IC package that includes at least one substrate that includes an ETS with embedded metal traces of multiple thicknesses for IC package height control (e.g., height reduction), including but not limited to the IC packages and related substrates in FIGS. 1 and 3-5 and according to any of the exemplary fabrication processes in FIGS. 6-8F.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include an embedded trace substrate (ETS) with embedded metal traces having multiple thickness for integrated circuit (IC) package height control. Related IC packages and IC package fabrication methods are also disclosed. The IC package includes a semiconductor die (“die”) that is coupled to a package substrate to provide signal routing paths to the die. The IC package also includes an ETS that includes metal traces embedded in an insulating layer(s) to provide connections for signal routing paths for the IC package. The package substrate coupled to the die can include an ETS. An interposer substrate that is included in a stacked-die IC package to provide an electrical interface between stacked die packages could also include an ETS. An ETS can be disposed on an outer side of a substrate in the IC package to facilitate interconnections between substrate and external interconnects (e.g., ball grid arrays (BGAs)) providing an external interface to the IC package. An ETS can also be disposed on an inner side of an interposer substrate in an IC package to facilitate interconnections between the interposer substrate and a package substrate. In either configuration, the thickness (i.e., height) of the embedded metal traces in the ETS contributes to the overall height of the IC package. In this regard, in exemplary aspects disclosed herein, to control (such as to reduce) the height of the IC package, the embedded metal traces embedded in an insulating layer in the ETS are provided to have multiple thicknesses (i.e., heights) in a vertical direction. The embedded metal traces in the ETS whose thicknesses affect the overall height of the IC package by being coupled to interconnects external to the ETS in the vertical direction, can be reduced in thickness to control (such as to reduce) IC package height. In this regard, some embedded metal traces in the ETS have a reduced thickness as compared to certain other embedded metal traces in the ETS. As an example, the embedded metal traces desired to be reduced in thickness could be selectively etched during the fabrication of the IC package. Thus, reducing the height of the embedded metal traces in an ETS whose thicknesses affect the height of its IC package reduces the overall height of the IC package.

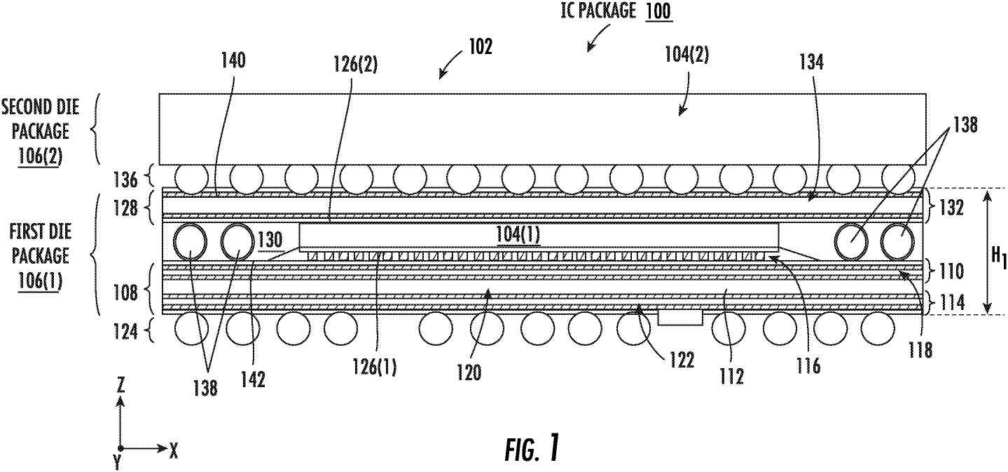

In this regard, FIG. 1 is a side view of an exemplary IC package 100. As will be discussed in more detail below, the IC package 100 includes a substrate that includes an ETS with embedded metal traces of reduced thickness to reduce the overall height of the IC package 100. In this example, the IC package 100 is a stacked-die IC package 102 that includes multiple dies 104(1), 104(2) that are included in respective first and second die packages 106(1), 106(2) that are stacked in top of each other in the vertical direction (Z-axis direction). The first die package 106(1) of the IC package 100 includes the first die 104(1) coupled to a package substrate 108. In this example, the package substrate 108 includes first, upper metallization layers 110 disposed on a core substrate 112. The core substrate 112 is disposed on second, bottom metallization layers 114. The first, upper metallization layers 110 provide an electrical interface for signal routing to the first die 104(1). The first die 104(1) is coupled to die interconnects 116 (e.g., raised metal bumps) that are electrically coupled to metal interconnects 118 in the first, upper metallization layers 110. The metal interconnects 118 in the first, upper metallization layers 110 are coupled to metal interconnects 120 in the core substrate 112, which are coupled to metal interconnects 122 in the second, bottom metallization layers 114. In this manner, the package substrate 108 provides interconnections between its first and second metallization layers 110, 114, and core substrate 112 to provide signal routing to the first die 104(1). External interconnects 124 (e.g., ball grid array (BGA) interconnects) are coupled to metal interconnects 122 in the second, bottom metallization layers 114 to provide interconnections through the package substrate 108 to the first die 104(1) through the die interconnects 116. In this example, a first, active side 126(1) of the first die 104(1) is adjacent to and coupled to the package substrate 108, and more specifically the first, upper metallization layers 110 of the package substrate 108.

In the example IC package 100 in FIG. 1, an additional optional second die package 106(2) is provided and coupled to the first die package 106(1) to support multiple dies. For example, the first die 104(1) in the first die package 106(1) may include an application processor, and the second die 104(1) may be a memory die, such as a dynamic random access memory (DRAM) die that provides memory support for the application processor. In this regard, in this example, the first die package 106(1) also includes an interposer substrate 128 that is disposed on a package mold 130 encasing the first die 104(1), adjacent to a second, inactive side 126(2) of the first die 104(1). The interposer substrate 128 also includes one or more metallization layers 132 that each includes metal interconnects 134 to provide interconnections to the second die 104(2) in the second die package 106(2). The second die package 106(2) is physically and electrically coupled to the first die package 106(1) by being coupled through external interconnects 136 (e.g., solder bumps, BGA interconnects) to the interposer substrate 128. The external interconnects 136 are coupled to the metal interconnects 134 in the interposer substrate 128.

To provide interconnections to route signals from the second die 104(2) through the external interconnects 136 and the interposer substrate 128 to the first die 104(1), vertical interconnects 138 (e.g., metal pillars, metal posts, metal vertical interconnect accesses (vias), such as through-mold vias (TMVs)) are disposed in the package mold 130 of the first die package 106(1). The vertical interconnects 138 extend from a first bottom surface 140 of the interposer substrate 128 to a first top surface 142 of the package substrate 108 in the vertical direction (Z-axis direction) in this example. The vertical interconnects 138 are coupled to metal interconnects 134 in the interposer substrate 128 adjacent first bottom surface 140 of the interposer substrate 128. The vertical interconnects 138 are also coupled to metal interconnects 118 in the first, upper metallization layers 110 of the package substrate 108 adjacent to the first top surface 142 of the package substrate 108. In this manner, the vertical interconnects 138 provide a bridge for interconnections, such as input/output (I/O) connections, between the interposer substrate 128 and the package substrate 108. This provides signal routing paths between the second die 104(2) in the second die package 106(1), and the first die 104(1) and external interconnects 124 through the package substrate.

Note that the IC package 100 in FIG. 1 could be a single die package that includes the first die package 106(1) and does not include the second die package 106(2). In this regard, the first die package 106(1) may not need to include the interposer substrate 128 and the vertical interconnects 138 to provide interconnections to the package substrate 108 for signal routing to the first die 104(1) and the external interconnects 124. In the example in FIG. 1, the stacked arrangement of the first and second die packages 106(1), 106(2) in the vertical direction (Z-axis direction) can save space in the horizontal axes (X- and/or Y-axes direction) by not having to dispose the second die 104(2) horizontally adjacent to the first die 104(1). However, stacking the first and second die packages 106(1), 106(2) in the vertical direction (Z-axis direction) can increase the overall height H₁ of the stacked first and second die packages 106(1), 106(2) in the IC package 100.

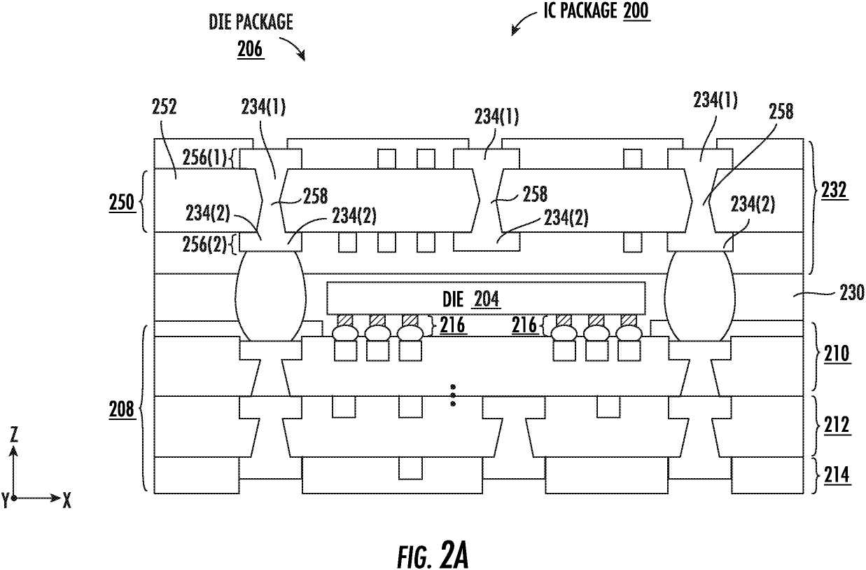

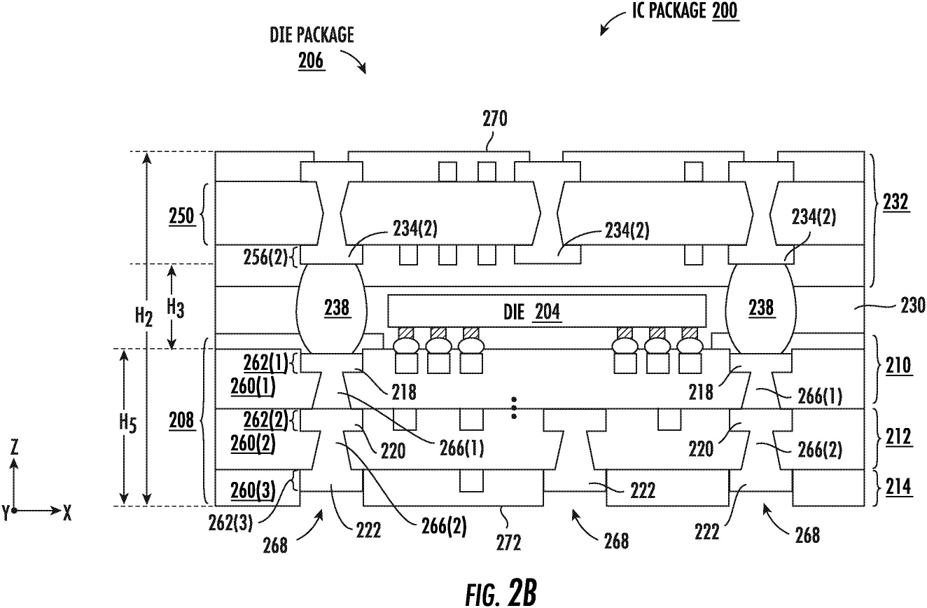

FIGS. 2A and 2B are detailed side views of a die package 206 that can be included as the first die package 106(1) in the IC package 100 in FIG. 1. The die package 206 in FIGS. 2A and 2B are part of an IC package 200. As shown in FIG. 2A, the die package 206 includes a die 204 that is coupled to a package substrate 208. The package substrate 208 includes the first, second, and third metallization layers 210, 212, 214 that can be the first, upper metallization layer 110, the core substrate 112, and the second, bottom metallization layer 114 in the IC package 100 in FIG. 1. An interposer substrate 232 is provided that is a two layer (2L) modified semi-additive process (mSAP) interposer substrate in this example. The interposer substrate 232 includes an insulating layer 250 that can be formed of a dielectric material 252. For example, the insulating layer 250 may be a laminate dielectric layer that is formed to provide a substrate. First metal interconnects 234(1) are formed in a first metal layer 256(1) adjacent to the insulating layer 250. Metal posts 258 (e.g., vias) are formed in the insulating layer 202 coupled between the first metal interconnects 234(1) in the first metal layer 256(1) and second metal interconnects 234(2) in a second metal layer 256(2), and are also coupled to the metal posts 258. This provides an interconnection, and thus a signal path, between the first and second metal interconnects 234(1), 234(2).

FIG. 2B also shows a side view of the IC package 200 in FIG. 2A. As shown in FIG. 2B, the package substrate 208 in the die package 206 is a 3 layer (3L) ETS package substrate, also referred to as “ETS” 208. The ETS 208 includes the respective first, second, and third metallization layers 210, 212, 214 referred to as “ETS metallization layers.” An ETS can facilitate providing higher density substrate interconnects to provide bump/solder joints for coupling to the die 204. The first, second, and third ETS metallization layers 210, 212, 214 are coreless structures in this example that includes metal traces embedded in a dielectric material for signal routing. In this regard, the first ETS metallization layers 210 include a first insulating layer 260(1) of a dielectric material. First metal interconnects 218 are formed as first embedded metal traces embedded in the first insulating layer 260(1). The first metal interconnects 218 are also referred to herein as first embedded metal traces 218. The first embedded metal traces 218 form a first metal layer 262(1) in the first insulating layer 260(1). Other embedded metal traces 264 are embedded in the first insulating layer 260(1) that provide interconnects for the die interconnects 216 to electrically couple the die 204 to the ETS 208.

Similarly, as shown in FIG. 2B, the second ETS metallization layer 212 includes a second insulating layer 260(2) of a dielectric material. Second metal interconnects 220 are formed as second embedded metal traces in the second insulating layer 260(2). The second metal interconnects 220 are also referred to herein as second embedded metal traces 220. The second embedded metal traces 220 form a second metal layer 262(2) in the second insulating layer 260(1). Similarly, the third ETS metallization layer 214 includes a third insulating layer 260(3) of a dielectric material. Third metal interconnects 222 are formed as third embedded metal traces in the third insulating layer 260(3). The third metal interconnects 222 are also referred to herein as third embedded metal traces 222. The third embedded metal traces 222 form a third metal layer 262(3) in the third insulating layer 260(3). Metal posts 266(1), 266(2) are formed in the first and second insulating layers 260(1), 260(2) to couple the embedded metal traces 218, 220 together and to the third embedded metal traces 222 in the third ETS metallization layer 214, to provide an interconnection path to the external interconnects that can be formed in openings 268 in the third insulating layer 260(3). In this regard, the third insulating layer 260(3) in this example is a solder resist layer to protect the third ETS metallization layer 214 when external interconnects are formed and coupled to exposed third embedded metal traces 222. The openings 268 are formed in the third ETS metallization layer 214 as a solder resist layer during fabrication of the die package 206 to provide a mechanism for aligning the formation of external interconnects in the openings 268 in contact with the third embedded metal traces 222.

With continuing reference to FIG. 2B, vertical interconnects 238 (e.g., metal pillars, metal posts, vias, TMVs, BGA interconnects) are disposed in a package mold 230 encasing the die 204 to provide interconnections between the interposer substrate 232 and the package substrate 208 for signal routing, like the vertical interconnects 238 in the first die package 106(1) in FIG. 1. The vertical interconnects 238 are disposed outside the die 204 in a horizontal direction (X- and/or Y-axis directions). The vertical interconnects 238 are coupled to the second metal interconnects 234(2) in the second metal layer 256(2) in the interposer substrate and the first embedded metal traces 218 in the first metal layer 262(1) in the first insulating layer 260(1) of the first ETS metallization layer 210. Thus, the vertical interconnects 238 form an electrical interconnection between the second metal interconnects 234(2) and the first embedded metal traces 218 to provide interconnects between the interposer substrate 232 and the package substrate 208. The vertical interconnects 238 are coupled to the second metal interconnects 234(2) and the first embedded metal traces 218 in the vertical direction (Z-axis direction). Thus, the overall height H₂ of the die package 206 in the vertical direction (Z-axis direction) is a function of the height H₃ of the vertical interconnects 238, the height H₄ of the interposer substrate 232 from the second metal interconnects 234(2) to a top surface 270 of the interposer substrate 232, and the height H₅ of the package substrate 208 from the first embedded metal traces 218 to a bottom surface 272 of the third ETS metallization layer 214.

It is desired to minimize the overall height of an IC package, such as the IC package 200. Thus, it is desired to minimize the overall height H₂ of the die package 206, because the height H₂ of the die package 206 contributes to the overall height of the IC package 200 that includes the die package 206. This may be particularly desirable as the complexity of IC packages increases and the number of I/O connections increase as a function of node reduction size in a die and an increase in the density of die connections.

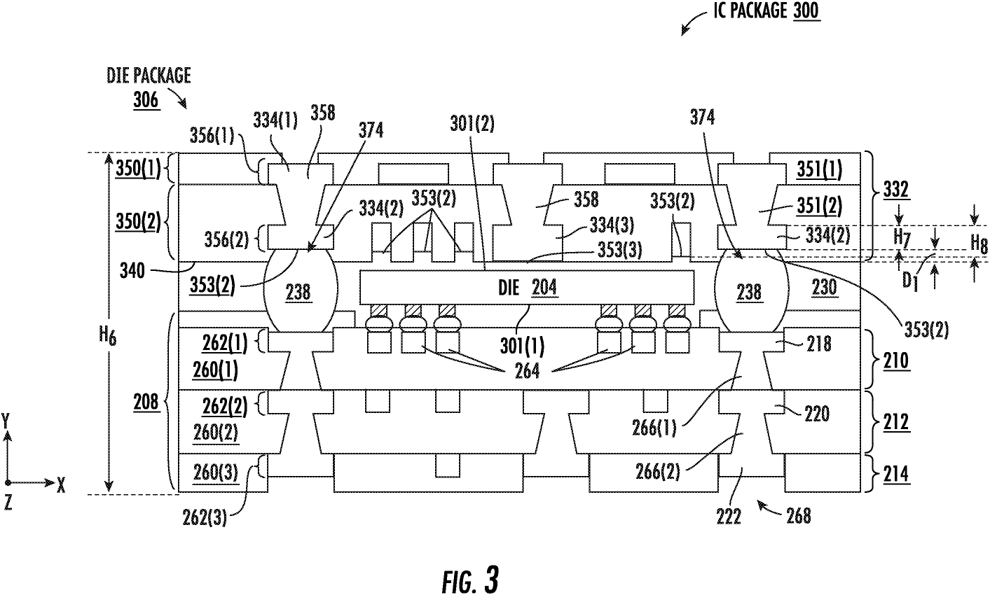

In this regard, FIG. 3 illustrates a side view of another exemplary die package 306 that is included in a die package 306 in an IC package 300. For example, the die package 306 in FIG. 3 could be included as the first die package 106(1) in the IC package 100. The die package 306 includes the die 204 in the IC package 200 in FIGS. 2A and 2B. The die 204 may be like the first die 104(1) in the first die package 106(1) in FIG. 1. The die 204 is coupled to the package substrate 208 that is the same as provided in the die package 206 in FIGS. 2A and 2B in this example, and thus does not need to be re-described for FIG. 3. The die 204 has a first, active side 301(1) that is coupled to the package substrate 208. The die 204 also has a second, inactive side 301(2) that is on the opposite side of the active side 301(1) of the die 204. The inactive side 301(2) of the die 204 is disposed adjacent to the interposer substrate 332. In this regard, the die 204 is disposed between the package substrate 208 and an interposer substrate 332 in the vertical direction (Z-axis direction). As discussed in more detail below, to reduce the overall height H₆ of the die package 306, and thus the overall height of the IC package 300 in which the die package 306 is included, embedded metal traces in an insulating layer in an ETS metallization layer that are coupled to the vertical interconnects 238 (e.g., metal pillars, metal posts, vias, TMVs, BGA interconnects) coupling an interposer substrate 332 to the package substrate 208, are reduced in thickness (i.e., height) in a vertical direction (Z-axis direction). The vertical interconnects 238 are disposed outside the die 204 in a horizontal direction (X- and/or Y-axis directions). As discussed in the example of the die package 206 in FIGS. 2A and 2B, the disposition of the embedded metal traces 218 in the first insulating layer 260(1) in the package substrate 208 that are coupled to the vertical interconnect 238 affect the overall height H₆ of the die package 306.

As discussed below, in the example die package 306 in FIG. 3, the interposer substrate 332 is provided as an ETS, unlike the interposer substrate 232 in the die package 206 in FIGS. 2A and 2B. An ETS has advantages discussed above of reduced thickness and the ability to facilitate embedded metal traces for reduced thickness metallization layers, with the metal traces having the ability to be embedded with a smaller line/spacing (L/S) ratio. The interposer substrate 332 in the die package 306 in FIG. 3 includes a second ETS metallization layer 350(2) that includes second embedded metal traces 334(2) embedded in a second insulating layer 351(2) that have a reduced thickness (i.e., height) in the vertical direction (Z-axis direction). This is accomplished in this example by the second embedded metal traces 334(2) being recessed a first distance D₁ below a first bottom surface 340 of the second ETS metallization layer 350(2), and more particularly the second insulating layer 351(2) in this example. As a non-limiting example, the recess distance D₁ could be between six (6) and twenty-one (21) micrometers (µm). A second metal surface 353(2) of the second embedded metal traces 334(2) is recessed from the first bottom surface 340 of the second insulating layer 351(2) of the second ETS metallization layer 350(2). The second embedded metal traces 334(2) are recessed in openings 374 formed in the second insulating layer 351(2) of the second ETS metallization layer 350(2) during fabrication. These reduced-height second embedded metal traces 334(2) are coupled to the vertical interconnects 238 that are disposed in the package mold 230 between the interposer substrate 332 and the package substrate 208. Thus, by recessing the second embedded metal traces 334(2) below the first bottom surface 340 of the second ETS metallization layer 350(2) and inside the openings 374, a portion of the vertical interconnects 238 can be formed inside the openings 374, using the openings 374 for alignment. A portion of the vertical interconnects 238 are formed inside the openings 374 in contact with the second embedded metal traces 334(2) embedded in the second insulating layer 351(2). This reduces the overall height H₆ of the die package 306, thus reducing the overall height of the IC package 300 that the die package 306 is provided, because a portion of the thickness (i.e., height) of the vertical interconnects 238 is disposed within the second ETS metallization layer 350(2), and more particularly the second insulating layer 351(2) of the second ETS metallization layer 350(2) in this example.

Note that as shown in FIG. 3, other third embedded metal traces 334(3) also embedded in the second insulating layer 351(2) of the second ETS metallization layer 350(2) are not recessed. A third metal surface 353(3) of these third embedded metal traces 334(3) extend adjacent to (could also extend to) the first bottom surface 340 of the second insulating layer 351(2) of the second ETS metallization layer 350(2) in this example. In this example, the height H₇ of the second embedded metal traces 334(2) is less than the height H₈ of the third embedded metal traces 334(3) in the second insulating layer 351(1). As a non-limiting example, the height H₇ of the second embedded metal traces 334(2) of reduced thickness could be between seven (7) and twelve (12) µm. As another non-limiting example, the height H₈ of the third embedded metal traces 334(3) could be between twelve (12) to twenty-seven (27) µm. This does not increase the overall height H₆ of the die package 306, because the vertical interconnects 238 are not coupled to these third embedded metal traces 334(3). Thus, in this example, these third embedded metal traces 334(3) are not recessed from the first bottom surface 340 of the second insulating layer 351(2) of the second ETS metallization layer 350(2). For example, these third embedded metal traces 334(3) may be used for routing interconnections within the interposer substrate 332 and not external to the interposer substrate 332 to the package substrate 208.

Also, as shown in FIG. 3, by recessing the second embedded traces 334(2) in the second insulating layer 351(2) of the second ETS metallization layer 350(2) in this example, this allows the second insulating layer 351(2) to function as a mask for forming the vertical interconnects 238. This is because the recessing of the second embedded metal traces 334(2) in this example form the openings 374 in the second insulating layer 351(2) above the second embedded metal traces 334(2). These openings 374 in the second insulating layer 351(2) form channels that can be used in fabrication to align the formation of the vertical interconnects 238 in the openings 374 to be coupled to the recessed second embedded metal traces 334(2) to form interconnections. At least a portion of the vertical interconnects 238 are disposed in the openings 374 and in contact with the second embedded metal traces 334(2). In this manner, a solder resist layer is not required to be provided and disposed on the first bottom surface 340 of the second insulating layer 351(2) to be used as a mask for the formation of the vertical interconnects 238 coupled to respective second embedded metal traces 334(2) in the second ETS metallization layer 350(2). A solder resist layer is not included in the die package 306 adjacent to the second ETS metallization layer 350(2) in this example.

Avoiding the need for use of a solder resist mask can also reduce the overall height H₆ of the die package 306, because a solder resist mask, when employed, is a layer that remains resident in the die package 306 after fabrication. To further avoid the need for a solder resist mask, the vertical interconnects 238 can be bonded to second embedded metal traces 334(2) in the ETS without the use of solder or solder joint (e.g., such as through direct metal bonding (e.g., copper bonding)) such that the interposer substrate 332 is solderless. Use of an ETS as a substrate with reduced thickness metal interconnects for forming interconnections with vertical interconnects, such as the interposer substrate 332 in FIG. 3, can avoid the need to provide any solder resist layer in the entire die package 306 or in an entire IC package 300 that includes the die package 306

Also, eliminating the use of a solder resist mask in the die package 306 in FIG. 3 can reduce a coefficient of thermal expansion (CTE) mismatch between the second embedded metal traces 334(2) and the vertical interconnects 238. The CTE of the second embedded metal traces 334(2) may be made of copper for example. The CTE of the second embedded metal traces 334(2) is relatively low as compared to the CTE of the solder resist layer. A solder resist layer may not be able to absorb the difference in thermal expansion to the second embedded metal traces 334(2) due to heat cycle during fabrication of the die package 306. The elimination of a solder resist mask can also reduce the CTE of the die package 306 to reduce warpage.

Note that the outer, external first ETS metallization layer 350(1) in the interposer substrate 332 could also be fabricated such that its first embedded metal traces 334(1) are also of a reduced thickness and recessed from an outer surface of the first insulating layer 351(1) of the first ETS metallization layer 350(1) to facilitate IC package height control (e.g., height reduction). External interconnects, such as external interconnects 136 in the IC package 100 in FIG. 1, are formed in contact with the first embedded metal traces 334(1). Thus, like the vertical interconnects 238 in FIG. 3, the external interconnects 136 being formed in contact with the first embedded metal traces 334(1) also affects the overall height of the IC package 300 in FIG. 3.

In this regard, FIG. 4 is a side view of another exemplary die package 406 that is included in an IC package 400. For example, the die package 406 in FIG. 4 could be included as the first die package 106(1) in the IC package 100. The die package 406 includes the die 204 in the die packages 206, 306 in FIGS. 2 and 3. The die 204 may be like the first die 104(1) in the first die package 106(1) in FIG. 1. The die 204 is coupled to the package substrate 208 that is the same as provided in the die package 306 in FIG. 3 in this example, and thus does not need to be re-described for FIG. 4. The die 204 has a first, active side 301(1) that is coupled to the package substrate 208 and a second, inactive side 301(2) that is disposed adjacent to an interposer substrate 432. In this regard, the die 204 is disposed between the package substrate 208 and the interposer substrate 432 in the vertical direction (Z-axis direction). As discussed in more detail below, to reduce the overall height H₉ of the die package 406 and thus the overall height of the IC package 400 in which the die package 406 is included, embedded metal traces in a first insulating layer 451 (1) in a first ETS metallization layer 450(1) of the interposer substrate 432 that are coupled to external interconnects 438 (e.g., metal bumps, metal interconnects, BGA interconnects) coupling the interposer substrate 432 to the package substrate 208 are reduced in thickness (i.e., height) in a vertical direction (Z-axis direction). As discussed above, the disposition of the second embedded metal traces 334(2) in the second insulating layer 351(2) of the second ETS metallization layer 350(1) that are coupled to the vertical interconnects 238 affect the overall height H₆ of the die package 306 in FIG. 3. Similarly, the disposition of the first embedded metal traces 434(1) in the first insulating layer 451(1) of the first ETS metallization layer 450(1) that are coupled to the external interconnects 438 affect the overall height H₉ of the die package 406 in FIG. 4.

In the example die package 406 in FIG. 4, the interposer substrate 432 is also provided as an ETS unlike the interposer substrate 232 in the die package 206 in FIGS. 2A and 2B. The interposer substrate 432 in the die package 406 in FIG. 4 includes a first ETS metallization layer 450(1) that includes the first embedded metal traces 434(1) embedded in a first insulating layer 451(1) that have a reduced thickness (i.e., height) in the vertical direction (Z-axis direction). This is accomplished in this example by the first embedded metal traces 434(1) being recessed a first distance D₂ below a first top surface 440 of the first insulating layer 451(1) of the first ETS metallization layer 450(1). As a non-limiting example, the recess distance D₂ could be between six (6) and twenty-one (21) micrometers (µm). A first metal surface 453(1) of the first embedded metal traces 434(1) is recessed from the first top surface 440 of the first insulating layer 451(1) of the first ETS metallization layer 450(1). The first embedded metal traces 434(1) are recessed in openings 474 formed in the first insulating layer 451(1) of the first ETS metallization layer 450(1) during fabrication. These reduced-height first embedded metal traces 434(1) are coupled to the external interconnects 438 that are disposed partially in the openings 474 and coupled to the first embedded metal traces 434(1). Thus, by recessing the first embedded metal traces 434(1) below the first top surface 440 of the first insulating layer 451(2) of the first ETS metallization layer 450(1) and inside the openings 474, a portion of the external interconnects 438 can be formed inside the openings 474, using the openings 474 for alignment. A portion of the external interconnects 438 are formed inside the openings 474 in contact with the first embedded metal traces 434(1) embedded in the first insulating layer 451(1). This reduces the overall height H₉ of the die package 406, thus reducing the overall height of the IC package 400 that the die package 406 is provided, because a portion of the thickness (i.e., height) of the external interconnects 438 is disposed within the first ETS metallization layer 450(1), and more particularly, the first insulating layer 451(1) of the first ETS metallization layer 450(1) in this example.

Note that as shown in FIG. 4, third embedded metal traces 434(3) also embedded in the first insulating layer 451(1) of the first ETS metallization layer 450(1) are not recessed. A third metal surface 453(3) of these third embedded metal traces 434(3) extend adjacent to (could also extend to) the first top surface 440 of the first insulating layer 451(1) of the first ETS metallization layer 450(1) in this example. In this example, the height H₁₀ of the first embedded metal traces 434(1) is less than the height H₁₁ of the third embedded metal traces 434(3) in the first insulating layer 451(1). As a non-limiting example, the height H₁₀ of the first embedded metal traces 434(1) of reduced thickness could be between seven (7) and twelve (12) µm. As another non-limiting example, the height H₁₁ of the third embedded metal traces 434(3) could be between 12 and 27 µm. This does not increase the overall height H₉ of the die package 406, because the external interconnects 438 are not coupled to these third embedded metal traces 434(3). Thus, in this example, these third embedded metal traces 434(3) are not recessed from the first top surface 440 of the first insulating layer 351(1) of the first ETS metallization layer 450(1). For example, these third embedded metal traces 434(3) may be used for routing interconnections within the interposer substrate 432 and not external to the interposer substrate 432 to the package substrate 208.

Also, as shown in FIG. 4, by recessing the first embedded traces 434(1) in the first insulating layer 451(1) of the first ETS metallization layer 450(1) in this example, this allows the first insulating layer 451(1) to function as a mask for forming the external interconnects 438. This is because the recessing of the first embedded metal traces 434(1) in this example form the openings 474 in the first insulating layer 451(1) above the first embedded metal traces 434(1). These openings 474 in the first insulating layer 351(1) form channels that can be used in fabrication to align the formation of the external interconnects 438 in the openings 474 to be coupled to the recessed first embedded metal traces 434(1) to form interconnections. At least a portion of the external interconnects 438 are disposed in the openings 474 and in contact with the first embedded metal traces 434(1). In this manner, a solder resist layer is not required to be provided and disposed on the first top surface 440 of the first insulating layer 351(1) to be used as a mask for the formation of the external interconnects 438 coupled to respective first embedded metal traces 434(1) in the first ETS metallization layer 450(1). A solder resist layer is not included in the die package 406 adjacent to the first ETS metallization layer 450(1) in this example.

Avoiding the need for use of a solder resist mask can also reduce the overall height H₉ of the die package 406, because a solder resist mask, when employed, is a layer that remains resident in the die package 406 after fabrication. To further avoid the need for a solder resist mask, the external interconnects 438 can be bonded to the first embedded metal traces 434(1) in the ETS without the use of solder or solder joint (e.g., such as through direct metal bonding (e.g., copper bonding)) such that the interposer substrate 432 is solderless. Use of an ETS as a substrate with reduced thickness metal interconnects for forming interconnections with external interconnects, such as the interposer substrate 432 in FIG. 4, can avoid the need to provide any solder resist layer in the entire die package 406 or in an entire IC package 400 that includes the die package 406.

Also, eliminating the use of a solder resist mask in the die package 406 in FIG. 4 can reduce a CTE mismatch between the first embedded metal traces 434(1) and the external interconnects 438. The CTE of the first embedded metal traces 434(1) may be made of copper for example. The CTE of the first embedded metal traces 434(1) is relatively low as compared to the CTE of the solder resist layer. A solder resist layer may not be able to absorb the difference in thermal expansion to the first embedded metal traces 434(1) due to heat cycle during fabrication of the die package 406. The elimination of a solder resist mask can also reduce the CTE of the die package 406 to reduce warpage.

Note that the outer, external third ETS metallization layer 214 in the package substrate 208 in the die packages 306, 406 in FIGS. 3 and 4 could also be fabricated such that its third metal embedded metal traces 222 are also of a reduced thickness and recessed from an outer surface of the bottom, third ETS metallization layer 214 to facilitate IC package height control (e.g., height reduction). External interconnects, such as external interconnects 136 in the IC package 100 in FIG. 1, are formed in contact with the bottom, third ETS metallization layer 214. Thus, like the external interconnects 438 in the die package 406 FIG. 4, the external interconnects being formed in contact with the third embedded metal traces 222 in the third ETS metallization layer 214 also affects the overall height of the IC package 400 in FIG. 4.

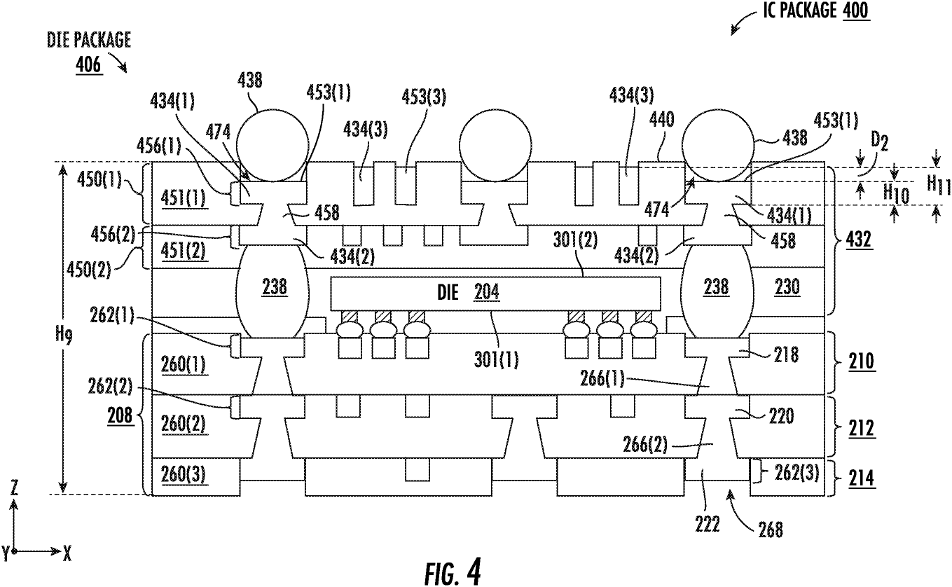

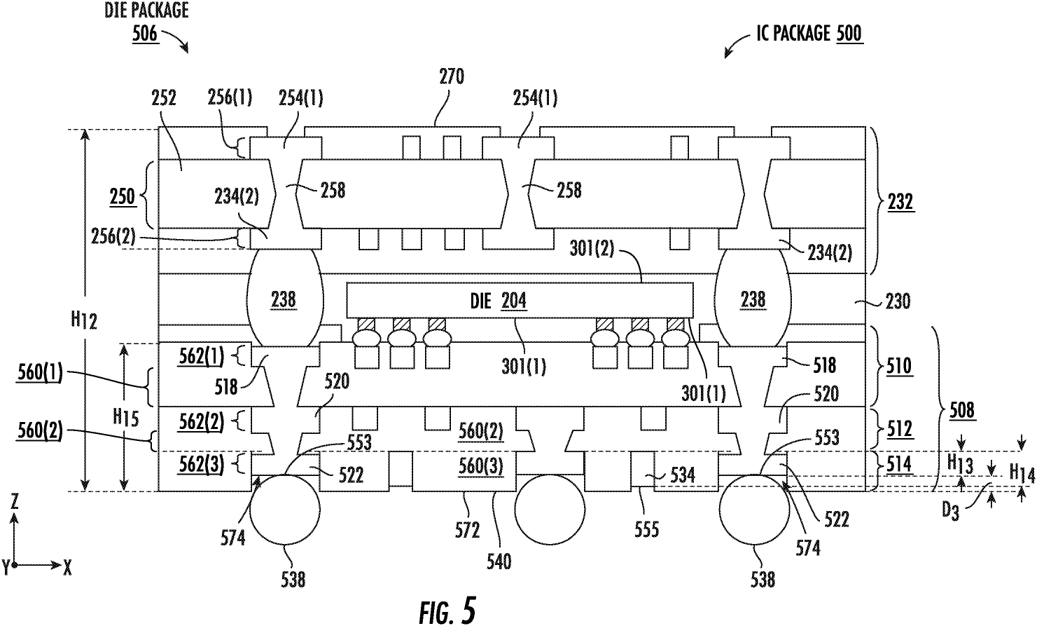

In this regard, FIG. 5 is a side view of another exemplary die package 506 that is included in an IC package 500. For example, the die package 506 in FIG. 5 could be included as the first die package 106(1) in the IC package 100. The die package 506 includes the die 204 in the die packages 206, 306, 406 in FIGS. 2-4. The die 204 may be like the first die 104(1) in the first die package 106(1) in FIG. 1. The die 204 is coupled to the interposer substrate 232 that is the same interposer substrate 232 as provided in the die package 206 in FIGS. 2A and 2B in this example, and thus does not need to be re-described for FIG. 5. The die 204 has a first, active side 301(1) that is coupled to the package substrate 508 and a second, inactive side 301(2) that is disposed adjacent to the interposer substrate 232. In this regard, the die 204 is disposed between the package substrate 508 and the interposer substrate 232 in the vertical direction (Z-axis direction). As discussed in more detail below, to reduce the overall height H₁₂ of the die package 506, and thus the overall height of the IC package 500 in which the die package 506 is included, the package substrate 508 includes a third, bottom ETS metallization layer 514 that includes third embedded metal traces 522 embedded in a third insulating layer 560(3) in a third ETS metallization layer 514. The third embedded metal traces 522 form a third metal layer 562(3) in the third insulating layer 560(3). The third embedded metal traces 522 are coupled to external interconnects 538 (e.g., metal bumps, metal interconnects, BGA interconnects) coupling the package substrate 508 to external interconnects 538. The third embedded metal traces 522 are reduced in thickness (i.e., height) in a vertical direction (Z-axis direction). The disposition of the third embedded metal traces 522 in the third insulating layer 560(3) of the third ETS metallization layer 514 that are coupled to the external interconnects 538 affect the overall height H₁₂ of the die package 506 in FIG. 5.

In the example die package 506 in FIG. 5, the package substrate 508 in the die package 506 includes common components with the package substrate 208 in the die package 206 in FIGS. 2A and 2B. These common components are shown with common element numbers between FIGS. 2 and 5 and are not re-described.

In this example, the package substrate 508 also includes a first metallization layer 510 that includes first metal interconnects 518 formed on a first insulating layer 560(1). In this example, the first metallization layer 510 is a first ETS metallization layer 510 and is referred to herein as the same. The first metal interconnects 518 form a first metal layer 562(1) on the first insulating layer 560(1). The first metal interconnects 518 are coupled to vertical interconnects 238. In this example, the package substrate 508 also includes a second metallization layer 512 that includes second metal interconnects 520 formed on a second insulating layer 560(2). In this example, the second metallization layer 512 is also a second ETS metallization layer 512 and is referred to as the same. The second metal interconnects 520 form a second metal layer 562(2) on the second insulating layer 560(2). The second metal interconnects 520 are coupled to first metal interconnects 518 in the first ETS metallization layer 510. The package substrate 508 also includes a third metallization layer 514 that includes third embedded metal traces 522 embedded in a third insulating layer 560(3). In this example, the third metallization layer 514 is also a third ETS metallization layer 514 and is referred to as the same. The third embedded metal traces 522 are coupled to second metal interconnects 520 in the second metallization layer 512. In this example, the third embedded metal traces 522 embedded in the third insulating layer 560(3) that have a reduced thickness (i.e., height) in the vertical direction (Z-axis direction). This is accomplished in this example by the third embedded metal traces 522 being recessed a distance D₃ below a first bottom surface 540 of the third insulating layer 560(3) of the third ETS metallization layer 514. As a non-limiting example, the recess distance D₃ could be between six (6) and twenty-one (21) micrometers (µm). A third metal surface 553 of the third embedded metal traces 522 is recessed from the first bottom surface 540 of the third insulating layer 560(3) of the third ETS metallization layer 514. The third embedded metal traces 522 are recessed in openings 574 formed in the third insulating layer 560(3) of the third ETS metallization layer 514 during fabrication.

These reduced-height third embedded metal traces 522 are coupled to the external interconnects 538 that are disposed partially in the openings 574 and coupled to the third embedded metal traces 522. Thus, by recessing the third embedded metal traces 522 above the first bottom surface 540 of the third insulating layer 560(3) of the third ETS metallization layer 514 and inside the openings 574, a portion of the external interconnects 538 can be formed inside the openings 574, using the openings 574 for alignment. A portion of the external interconnects 538 are formed inside the openings 574 in contact with the third embedded metal traces 522 embedded in the third insulating layer 560(3). This reduces the overall height H₁₂ of the die package 506, thus reducing the overall height of the IC package 500 that the die package 506 is provided, because a portion of the thickness (i.e., height) of the external interconnects 538 is disposed within the third ETS metallization layer 514, and more particularly the third insulating layer 560(3) of the third ETS metallization layer 514 in this example.

Note that as shown in FIG. 5, other embedded metal traces 534 also embedded in the third insulating layer 560(3) of the third ETS metallization layer 514 are not recessed. A first surface 555 of these other embedded metal traces 534 extends either to or adjacent to the first bottom surface 540 of the third insulating layer 560(3) of the third ETS metallization layer 514 in this example. In this example, the height H₁₃ of the third embedded metal traces 522 is less than the height H₁₄ of these other embedded metal traces 534 in the third insulating layer 560(3). As a non-limiting example, the height H₁₃ of the third embedded metal traces 522 of reduced thickness could be between seven (7) and twelve (12) µm. As another non-limiting example, the height H₁₄ of the other embedded metal traces 534 could be between twelve (12) to twenty-seven (27) µm. This does not increase the overall height H₁₂ of the die package 506, because the external interconnects 538 are not coupled to these other embedded metal traces 534. Thus, in this example, these other embedded metal traces 534 are not recessed from the bottom surface 572 of the third insulating layer 560(3) of the third ETS metallization layer 514. For example, these other embedded metal traces 534 may be used for routing interconnections within the package substrate 532 and not external between the package substrate 208 and external interconnects 538.

Also, as shown in FIG. 5, by recessing the third embedded traces 522 in the third insulating layer 560(3) of the third ETS metallization layer 514 in this example, this allows the third insulating layer 560(3) to function as a mask for forming the external interconnects 538. This is because the recessing of the third embedded metal traces 522 in this example form the openings 574 in the third insulating layer 560(3) above the third embedded metal traces 522. These openings 574 in the third insulating layer 560(3) form channels that can be used in fabrication to align the formation of the external interconnects 538 in the openings 574 to be coupled to the recessed third embedded metal traces 522 to form interconnections. At least a portion of the external interconnects 538 are disposed in the openings 574 and in contact with the third embedded metal traces 522. In this manner, a solder resist layer is not required to be provided and disposed on the first bottom surface 540 of the third insulating layer 560(3) to be used as a mask for the formation of the external interconnects 538 coupled to respective third embedded metal traces 522 in the third ETS metallization layer 514. A solder resist layer is not included in the die package 506 adjacent to the third ETS metallization layer 514 in this example.

Avoiding the need for use of a solder resist mask can also reduce the overall height His of the package substrate 508 and thus the overall height H₁₂ of the die package 506, because a solder resist mask, when employed, is a layer that remains resident in the die package 506 after fabrication. To further avoid the need for a solder resist mask, the external interconnects 538 can be bonded to the third embedded metal traces 522 in the ETS without the use of solder or solder joint (e.g., such as through direct metal bonding (e.g., copper bonding)) such that the package substrate 508 is solderless. Use of an ETS as a substrate with reduced thickness metal interconnects for forming interconnections with external interconnects, such as the package substrate 508 in FIG. 5, can avoid the need to provide any solder resist layer in the entire die package 506 or in an entire IC package 500 that includes the die package 506.

Also, eliminating the use of a solder resist mask in the die package 506 in FIG. 5 can reduce a CTE mismatch between the third embedded metal traces 522 and the external interconnects 538. The CTE of the third embedded metal traces 522 may be made of copper for example. The CTE of the third embedded metal traces 522 is relatively low as compared to the CTE of the solder resist layer. A solder resist layer may not be able to absorb the difference in thermal expansion to the third embedded metal traces 522 due to heat cycle during fabrication of the die package 506. The elimination of a solder resist mask can also reduce the CTE of the die package 506 to reduce warpage.

Note that the first ETS metallization layer 510 in the package substrate 508 in the die package 506 in FIG. 5 could also be fabricated such that its first metal interconnects 518 are of a reduced thickness and recessed from an outer surface of the upper, first ETS metallization layer 510 to facilitate IC package height control (e.g., height reduction). Vertical interconnects, such as vertical interconnects 238 in the die package 206 of the IC package 200 in FIGS. 2A and 2B, can be formed in contact with the upper, first ETS metallization layer 510. Thus, the vertical interconnects 238 being formed in contact with the first metal interconnects 518 of a reduced thickness and recessed in the first ETS metallization layer 510 also affects the overall height of the IC package 500 in FIG. 5.

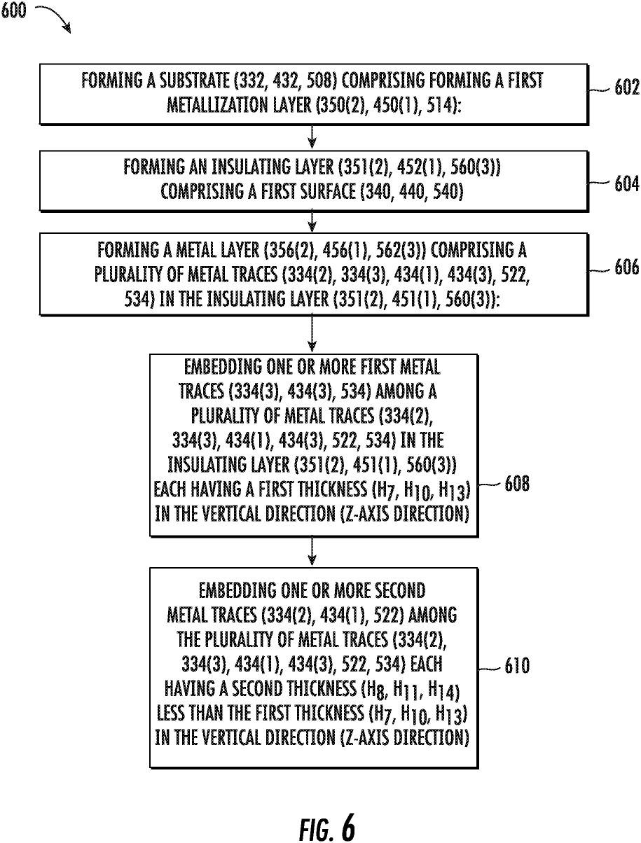

FIG. 6 is a flowchart illustrating an exemplary fabrication process 600 of fabricating an IC package that includes at least one substrate that includes an ETS with embedded metal traces with embedded metal traces of multiple thicknesses for IC package height control (e.g., height reduction), including but not limited to the IC packages and related die packages 306, 406, 506 in FIGS. 3-5. The fabrication process in FIG. 6 will be discussed in conjunction with the die packages 306, 406, 506 in FIGS. 3-5.

In this regard, a first step in the fabrication process 600 can be forming an interposer substrate 332, 432, 508 (e.g., interposer substrates 332, 432 or package substrate 508) comprising forming a first metallization layer 350(2), 450(1), 514 (block 602 FIG. 6). Forming a first metallization layer 350(2), 450(1), 514 can include forming an insulating layer 351(2), 451(1), 560(3) comprising a first surface 340, 440, 540 (block 604 in FIG. 6), and forming a metal layer 356(2), 456(1), 562(3) comprising a plurality of metal traces 334(2), 334(3), 434(1), 434(3), 522, 534 in the insulating layer 351(2), 451(1), 560(3) (block 606 in FIG. 6). Forming the metal layer 356(2), 456(1), 562(3) comprising a plurality of metal traces 334(2), 334(3), 434(1), 434(3), 522, 534 in the insulating layer 351(2), 451(1), 560(3) can include embedding one or more first metal traces 334(3), 434(3), 534 among a plurality of metal traces 334(2), 334(3), 434(1), 434(3), 522, 534 in the insulating layer 351(2), 451(1), 560(3), the one or more each first metal traces 334(3), 434(3), 534 having a first thickness H₇, H₁₀, H₁₃ in the vertical direction (block 608 in FIG. 6). Forming the metal layer 356(2), 456(1), 562(3) can also include embedding one or more second metal traces 334(2), 434(1), 522 among the plurality of metal traces 334(2), 334(3), 434(1), 434(3), 522, 534, one or more second metal traces 334(2), 434(1), 522 each having a second thickness H₇, H₁₀, H₁₃ less than the first thickness H₈, H₁₁, H₁₄ (block 610 in FIG. 6).

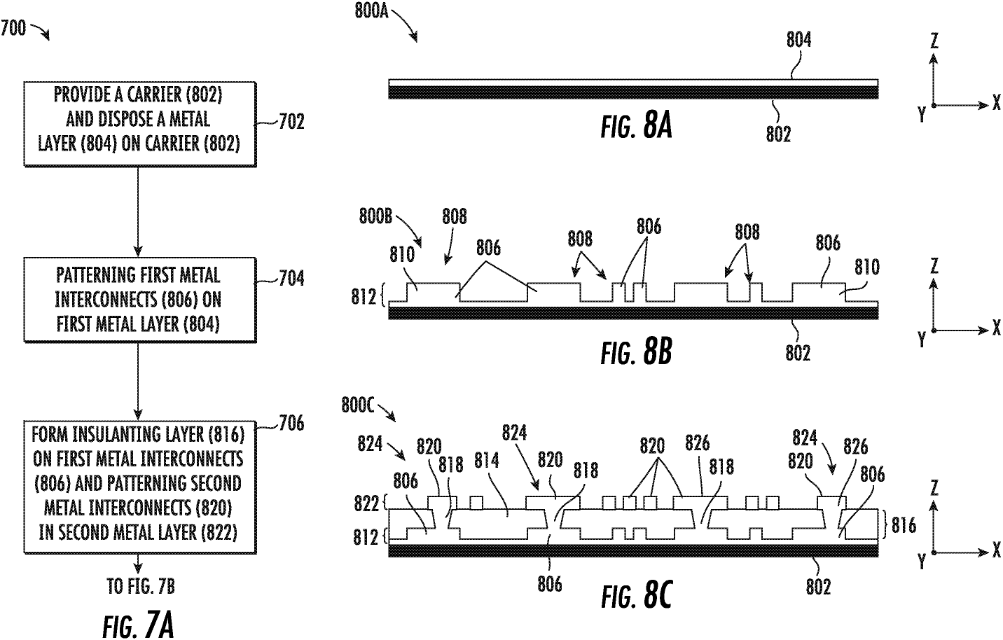

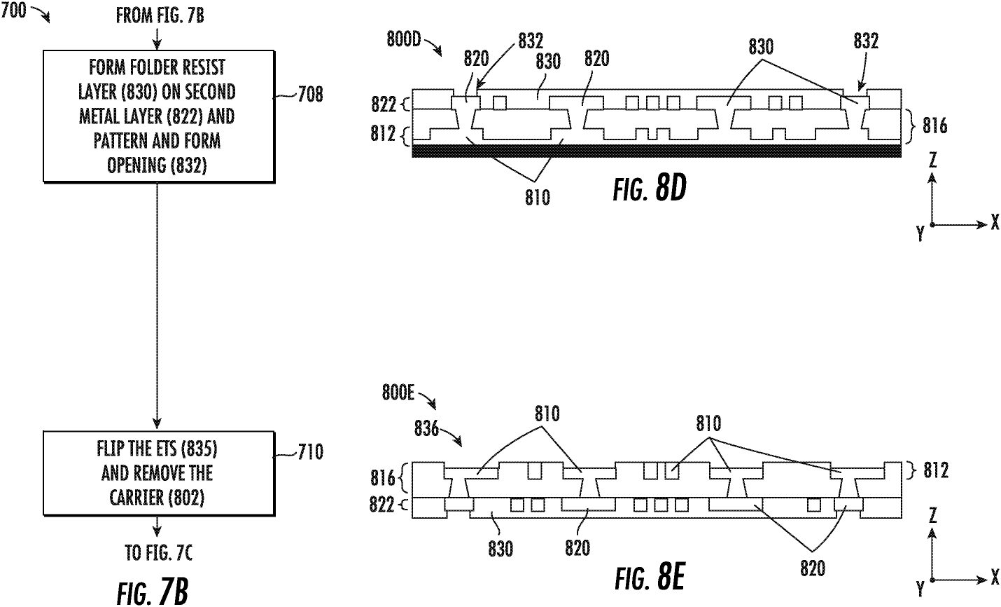

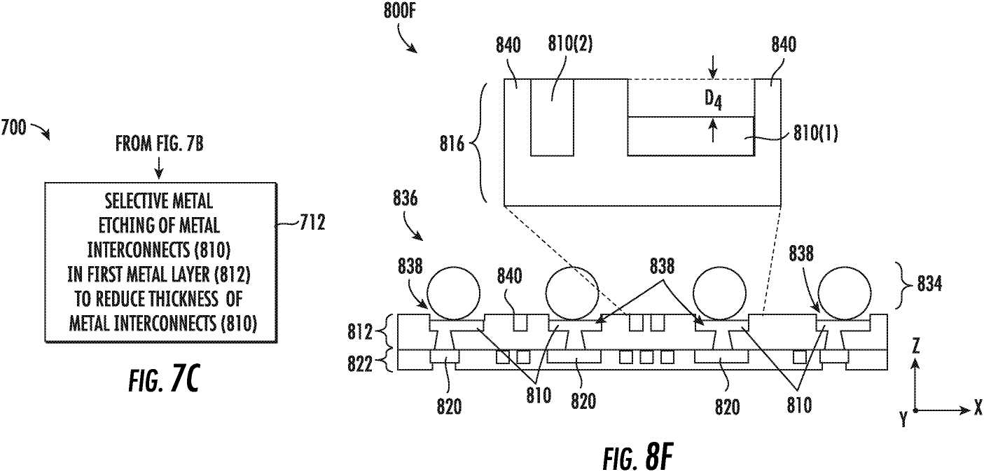

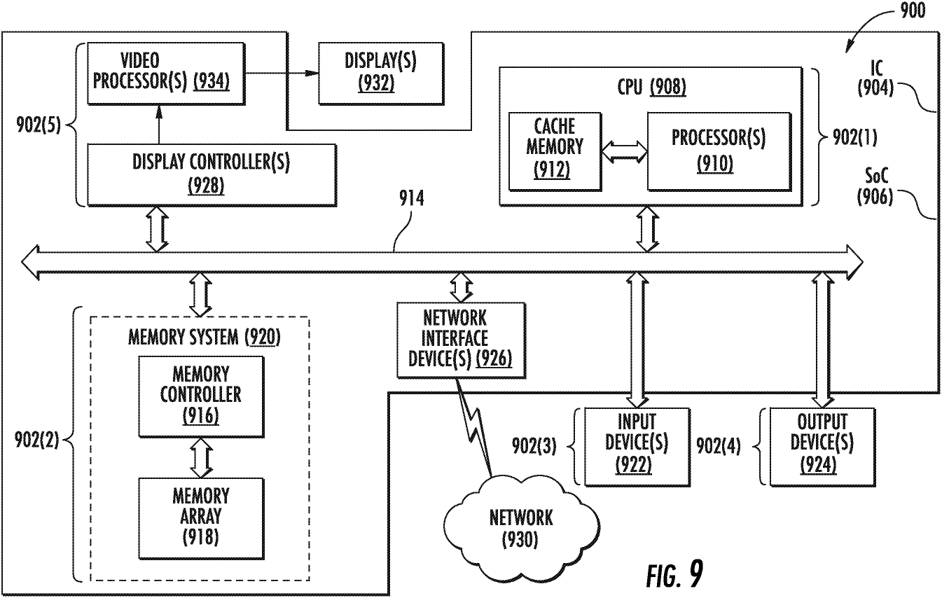

Oher fabrication processes can be employed to fabricate an ETS with embedded metal traces of multiple thicknesses for IC package height control (e.g., height reduction), including but not limited to the IC packages and related die packages 306, 406, 506 in FIGS. 3-5. The fabrication process in FIG. 6 will be discussed in conjunction with the die packages 306, 406, 506 in FIGS. 3-5. In this regard, FIGS. 7A-7C is a flowchart illustrating another exemplary fabrication process 700 to fabricate an ETS with embedded metal traces of multiple thicknesses for IC package height control (e.g., height reduction), including but not limited to the IC packages and related die packages 306, 406, 506 in FIGS. 3-5. The fabrication process in FIG. 6 will be discussed in conjunction with the die packages 306, 406, 506 in FIGS. 3-5. FIGS. 8A-8F are exemplary fabrication stages 800A-800F during fabrication of an IC package according to the fabrication process in FIGS. 7A-7C. The exemplary fabrication stages 800A-800F of the fabrication process 700 in FIGS. 7A-7C will be discussed in conjunction with the exemplary fabrication stages 800A-800F in FIGS. 8A-8F.

In this regard, as shown in the exemplary fabrication stage 800A in FIG. 8A, a first step in fabricating an ETS with embedded metal traces of multiple thicknesses for IC package height control (e.g., height reduction) can include providing a carrier 802 and forming a metal layer 804 on the carrier 802 as a seed layer for formation of metal interconnects in a metal layer (block 702 in FIG. 7A). For example, the metal layer 804 may be a copper layer. As shown in the exemplary fabrication stage 800B in FIG. 8B, a next step in fabricating an ETS with embedded metal traces of multiple thicknesses for IC package height control (e.g., height reduction) can include patterning first metal interconnects 806 on the metal layer 804 (block 704 in FIG. 7A). This can include disposing a photoresist layer on the metal layer 804, and then patterning the photoresist layer to form openings 808 in the photoresist layer where it is desired to form metal interconnects. Then, a metal material 810 can be disposed in the openings 808 to form a first metal layer 812 of a plurality of first metal interconnects 806. The first metal interconnects 806 are embedded metal traces in this example. As shown in the exemplary fabrication stage 800C in FIG. 8C, a next step in fabricating an ETS with embedded metal traces of multiple thicknesses for IC package height control (e.g., height reduction) can include disposing a dielectric material 814 on the first metal interconnects 806 to form an insulating layer 816 such that the first metal interconnects 806 are embedded metal traces within the dielectric material 814 (block 706 in FIG. 7A). This can include laminating the dielectric material 814 on the first metal interconnects 806. Metal posts 818 can be formed in the insulating layer 816 in contact with the first metal interconnects 806. The same process of patterning can also be employed to form additional, second metal interconnects 820 in an adjacent formed second metal layer 822 that are coupled to the metal posts 818 and first metal interconnects 806. This can include disposing a photoresist layer on the insulating layer 816, and then patterning the photoresist layer to form openings 824 in the photoresist layer where it is desired to form the second metal interconnects 820. Then, a metal material 826 can be disposed in the openings 824 to form a second metal layer 828 of a plurality of second metal interconnects 820.

As shown in the exemplary fabrication stage 800D in FIG. 8D, a next step in fabricating an ETS with embedded metal traces of multiple thicknesses for IC package height control (e.g., height reduction) can include forming a solder resist layer 830 on the second metal layer 822 above the second metal interconnects 820 to form openings 832 over select second metal interconnects 820 (block 708 in FIG. 7B). The openings 832 are formed in the solder resist layer 830 using a photoresist layer and patterning process. Forming the openings 832 in the solder resist layer 830 allows the solder resist layer 830 to act as a mask for the future formation of external interconnects 834 in the openings 832 using the openings 832 for alignment (see FIG. 8F). As shown in the exemplary fabrication stage 800E in FIG. 8E, a next step in fabricating an ETS with embedded metal traces of multiple thicknesses for IC package height control (e.g., height reduction) can include flipping the ETS 836 and removing the carrier 802 (block 710 in FIG. 7B). As shown in the exemplary fabrication stage 800F in FIG. 8F, a next step in fabricating an ETS with embedded metal traces of multiple thicknesses for IC package height control (e.g., height reduction) can include selective metal etching of the metal interconnects 810 in the first metal layer 812 to selectively reduce the thickness and recess certain metal interconnects 810 (block 712 in FIG. 7C). The selective etching of the metal interconnects 810 form openings 838 in a surface 840 in the insulating layer 816 such that the metal interconnects 810 are recessed from the surface 840 in the openings 838. In this example, the metal interconnects 810 are recessed distance D₄ from the surface 840 of the insulating layer 816.

Note that although the examples of the die packages 306, 406, and 506 in FIGS. 3-5, respectively, show either one substrate (either the interposer substrate or the package substrate) as having an ETS with embedded metal traces of multiple thicknesses for IC package height control (e.g., height reduction), note that such an ETS could be provided in both the interposer substrate and the package substrate of the die packages 306, 406, and 506. Also note that the ETS with embedded metal traces of multiple thicknesses for IC package height control (e.g., height reduction) could be provided in either or both of the interposer substrate and the package substrate of the die packages 306, 406, and 506 in both an internal ETS metallization adjacent to a die and an external ETS metallization layer not directly adjacent to the die and disposed on an outside, outer metallization layer of the substrate. Any of these combinations is contemplated in this disclosure and any combinations of interposer substrate and package substrate in the die packages 306, 406, and 506 can be provided in a die package and/or an IC package.

IC packages that include at least one substrate that includes an ETS with embedded metal traces of multiple thicknesses for IC package height control (e.g., height reduction), including but not limited to the IC packages and related substrates in FIGS. 1 and 3-5 and according to any of the exemplary fabrication processes in FIGS. 6-8F, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

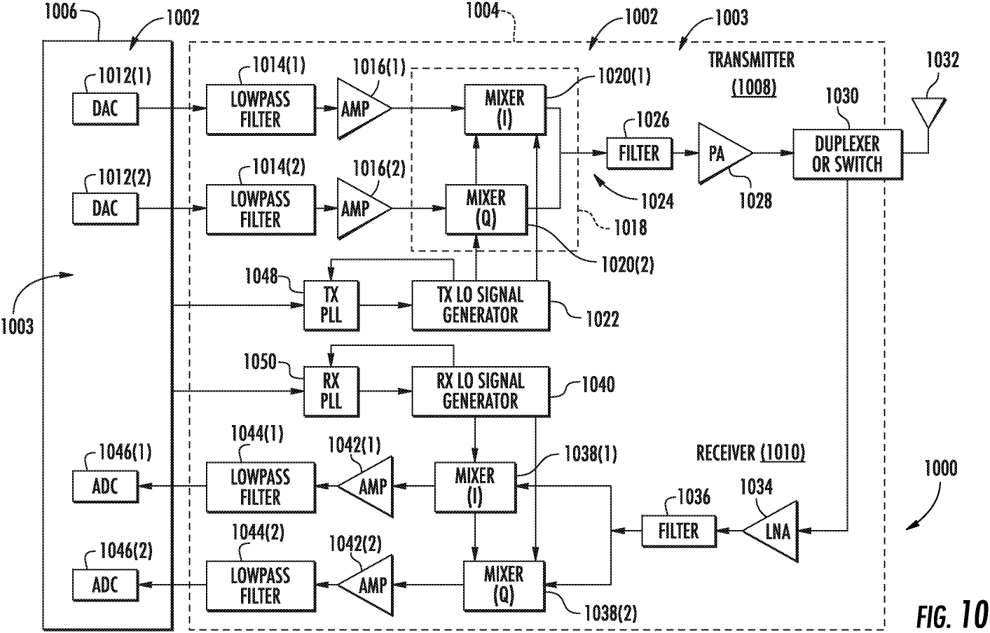

In this regard, FIG. 9 illustrates a block diagram of a processor-based system 900 including a circuit that can be provided in an IC package 902 that includes at least one substrate that includes an ETS with embedded metal traces of multiple thicknesses for IC package height control (e.g., height reduction), including but not limited to the IC packages and related substrates in FIGS. 1 and 3-5 and according to any of the exemplary fabrication processes in FIGS. 6-8F, and according to any aspects disclosed herein. In this example, the processor-based system 900 may be formed as an IC 904 in an IC package 902 and as a system-on-a-chip (SoC) 906. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. Each of the memory system 920, the one or more input devices 922, the one or more output devices 924, the one or more network interface devices 926, and the one or more display controllers 928 can be provided in the same or different IC packages 902. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display controller(s) 928 and video processor(s) 934 can be included as ICs in the same or different IC packages 902, and in the same or different IC package 902 containing the CPU 908, as an example. The display(s) 932 can include any type of display, including, but not limited to, a cathode ray tube (CRT), a liquid crystal display (LCD), a plasma display, a light emitting diode (LED) display, etc.

FIG. 10 illustrates a block diagram of an exemplary wireless communications device 1000 that includes radio-frequency (RF) components formed from one or more ICs 1002, wherein any of the ICs 1002 can be included in an IC package 1003 that includes at least one substrate that includes an embedded trace substrate (ETS) with embedded metal traces of multiple thicknesses for IC package height control (e.g., height reduction), including but not limited to the IC packages and related substrates in FIGS. 1 and 3-5, and according to any of the exemplary fabrication processes in FIGS. 6-8F, and according to any aspects disclosed herein. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a substrate comprising a first metallization layer, comprising:
      an insulating layer comprising a first surface; and
      a metal layer comprising a plurality of metal traces embedded in the insulating layer; and
   wherein:
      one or more first metal traces among the plurality of metal traces, the one or more first metal traces each having a first thickness in a vertical direction; and
      one or more second metal traces among the plurality of metal traces, the one or more second metal traces each having a second thickness less than the first thickness in the vertical direction.
2. The IC package of clause 1, wherein:
   the one or more second metal traces among the plurality of metal traces each comprise a second metal surface recessed a second distance from a first outer surface of the insulating layer.
3. The IC package of clause 2, wherein:
   the one or more first metal traces among the plurality of metal traces each comprise a second metal surface recessed a first distance greater than the second distance from the first outer surface of the insulating layer.
4. The IC package of clause 1 or 2, wherein:
   the one or more first metal traces among the plurality of metal traces each comprise a first metal surface extending to a first outer surface of the insulating layer; and
   the one or more second metal traces among the plurality of metal traces each comprise a second metal surface recessed from the first outer surface of the insulating layer.
5. The IC package of any of clauses 1 to 4, further comprising one or more openings in the first surface of the insulating layer;
   wherein the one or more second metal traces are each disposed in an opening among the one or more openings below the first surface of the insulating layer.
6. The IC package of any of clauses 1 to 5, wherein the substrate does not comprise a solder resist layer adjacent to the first metallization layer.
7. The IC package of any of clauses 1 to 6, further comprising one or more interconnects each coupled to a second metal trace among the one or more second metal traces;
   wherein the one or more interconnects are each direct metal bonded to a second metal trace among the one or more second metal traces.
8. The IC package of any of clauses 1 to 7, further comprising one or more interconnects each coupled to a second metal trace among the one or more second metal traces; and
   further not comprising a solder joint coupling any of the one or more interconnects to the second metal trace among the one or more second metal traces.
9. The IC package of any of clauses 1 to 8, wherein the substrate comprises a second metallization layer, and further comprising:
   a die coupled to the second metallization layer; and
   one or more external interconnects each coupled to a second metal trace among the one or more second metal traces.
10. The IC package of clause 9, further comprising one or more openings in the first surface of the insulating layer;
   the one or more second metal traces each disposed in an opening among the one or more openings; and
   the one or more external interconnects are each at least partially disposed in an opening among the one or more openings and coupled to the second metal trace among the one or more second metal traces in the opening.
11. The IC package of clause 9 or 10, wherein:
   the die comprises a first side and a second side opposite the first side; and
   the first side of the die is coupled to the second metallization layer of the substrate; and
   further comprising an interposer substrate adjacent to the second side of the die, such that the die is disposed between the substrate and the interposer substrate.
12. The IC package of clause 11, further comprising a plurality of vertical interconnects disposed outside the die in a horizontal direction,
   wherein:
      the interposer substrate comprises a third metallization layer comprising a plurality of third metal interconnects; and
      each vertical interconnect among the plurality of vertical interconnects couples a third metal interconnect among the plurality of third metal interconnects, to a second metal interconnect among a plurality of second metal interconnects.
13. The IC package of any of clauses 1 to 9, further comprising:
   a die comprising a first side and a second side opposite the first side,
      the first side of the die is coupled to the first metallization layer of the substrate; and
   an interposer substrate adjacent to the second side of the die, such that the die is disposed between the substrate and the interposer substrate; and
   a plurality of vertical interconnects disposed outside the die in a horizontal direction,
   wherein:
      the interposer substrate comprises a third metallization layer comprising a plurality of third metal interconnects; and
      each vertical interconnect among the plurality of vertical interconnects couples a third metal interconnect among the plurality of third metal interconnects in the third metallization layer of the interposer substrate, to a second metal trace among the one or more second metal traces.
14. The IC package of clause 13, further comprising a plurality of die interconnects each coupled to the first side of the die and each coupled to a first metal trace among the one or more first metal traces.
15. The IC package of clause 14, further comprising one or more openings in a first outer surface of the insulating layer;
   the one or more second metal traces each disposed in an opening among the one or more openings; and
   the plurality of vertical interconnects are each at least partially disposed in an opening among the one or more openings and are each coupled to a second metal trace among the one or more second metal traces in the opening.
16. The IC package of any of clauses 1-9, further comprising:
   a package substrate; and
   a die comprising a first side and a second side opposite the first side, wherein the first side of the die is coupled to the package substrate;
   wherein the substrate comprises an interposer substrate adjacent to the second side of the die, such that the die is disposed between the substrate and the interposer substrate.
17. The IC package of clause 16, further comprising a plurality of vertical interconnects disposed outside the die in a horizontal direction,
   wherein each vertical interconnect among the plurality of vertical interconnects couples to a second metal trace among the one or more second metal traces, to the package substrate.
18. The IC package of clause 17, further comprising one or more openings in the first surface of the insulating layer;
   the one or more second metal traces each disposed in an opening among the one or more openings; and
   the plurality of vertical interconnects each at least partially disposed in an opening among the one or more openings and coupled to a second metal trace among the one or more second metal traces in the opening.
19. The IC package of clause 16, further comprising one or more external interconnects each coupled to a second metal trace among the one or more second metal traces.
20. The IC package of clause 19, further comprising one or more openings in a first outer surface of the insulating layer;
   the one or more second metal traces each disposed in an opening among the one or more openings; and
   the one or more external interconnects are each at least partially disposed in an opening among the one or more openings and coupled to a second metal trace among the one or more second metal traces in the opening.
21. The IC package of clause 19 or 20, further comprising a plurality of vertical interconnects disposed outside the die in a horizontal direction,
   wherein each vertical interconnect among the plurality of vertical interconnects couples a second metal trace among the one or more second metal traces, to the package substrate.
22. The IC package of any of clauses 1 to 21, further comprising:
   a first die comprising a first side and a second side opposite the first side, wherein the first side of the first die is coupled to the substrate;
   an interposer substrate adjacent to the second side of the first die, such that the first die is disposed between the substrate and the interposer substrate; and
   a second die coupled to the interposer substrate such that the interposer substrate is disposed between the first die and the second die.
23. The IC package of any of clauses 1 to 22 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
24. A method of fabricating a substrate for an integrated circuit (IC) package, comprising:
   forming a substrate comprising forming a first metallization layer, comprising:
      forming an insulating layer comprising a first surface; and
      forming a metal layer comprising a plurality of metal traces in the
         insulating layer, comprising:
         embedding one or more first metal traces among a plurality of metal traces, the one or more first metal traces each having a first thickness in a vertical direction; and
         embedding one or more second metal traces among the plurality of metal traces, the one or more second metal traces each having a second thickness less than the first thickness in the vertical direction.
25. The method of clause 24, further comprising:
   forming one or more openings in a first outer surface of the insulating layer; and
   disposing each of the one or more second metal traces in an opening among the one or more openings below the first surface of the insulating layer.
26. The method of clause 24 or 25, further comprising not forming a solder resist layer adjacent to the first metallization layer.
27. The method of any of clauses 24 to 26, further comprising:
   forming one or more interconnects each coupled to a second metal trace among the one or more second metal traces; and
   metal bonding each of the one or more interconnects to the second metal trace among the one or more second metal traces.
28. The method of any of clauses 24 to 27, further not comprising a solder joint coupling any of the one or more interconnects, to a second metal trace among the one or more second metal traces.
29. The method of any of clauses 24 to 28, further comprising:
   coupling a first side of a first die to the substrate;
   disposing an interposer substrate adjacent to a second side of the first die opposite the first side of the first die, such that the first die is disposed between the substrate and the interposer substrate; and
   coupling a second die to the interposer substrate, such that the interposer substrate is disposed between the first die and the second die.
30. The method of any of clauses 24 to 29, further comprising:
   coupling a die coupled to a second metallization layer in the substrate; and
   coupling one or more external interconnects to a second metal trace among the one or more second metal traces.
31. The method of clause 30, further comprising:
   forming one or more openings in a first outer surface of the insulating layer;
   disposing each of the one or more second metal traces in an opening among the one or more openings; and
   disposing each of the one or more external interconnects at least partially in an opening among the one or more openings and coupling to the second metal trace among the one or more second metal traces in the opening.
32. The method of clause 30 or 31, further comprising:
   coupling a first side of a first die to the second metallization layer of the substrate; and
   disposing an interposer substrate adjacent to a second side of the die opposite the first side of the die, such that the die is disposed between the substrate and the interposer substrate.
33. The method of clause 32, further comprising:
   coupling each of a plurality of vertical interconnects disposed outside the die in a horizontal direction to a metal interconnect among a plurality of metal interconnects in a third metallization layer of the interposer substrate; and
   coupling each of the plurality of vertical interconnects to a second metal interconnect among a plurality of second metal interconnects in the second metallization layer of the substrate.
34. The method of any of clauses 24 to 29, further comprising:
   coupling a first side of a first die to the first metallization layer of the substrate;
   disposing an interposer substrate adjacent to a second side of the first die opposite the first side of the first die, such that the first die is disposed between the substrate and the interposer substrate; and
   coupling a plurality of vertical interconnects disposed outside the first die in a horizontal direction, each of the plurality of vertical interconnects coupling a metal interconnect among the plurality of metal interconnects in a third metallization layer of an interposer substrate, to a second metal trace among the one or more second metal traces.
35. The method of clause 34, further comprising coupling each of a plurality of die interconnects to the first side of the die and to a first metal trace among the one or more first metal traces.
36. The method of clause 35, further comprising:
   forming one or more openings in a first outer surface of the insulating layer;
   disposing each of the one or more second metal traces in an opening among the one or more openings; and
   disposing each of the plurality of vertical interconnects at least partially in an opening among the one or more openings and coupling to the second metal trace among the one or more second metal traces in the opening.
37. The method of any of clauses 24 to 29, further comprising:
   providing a package substrate;
   coupling a first side of a die to the package substrate; and
   disposing the substrate comprises an interposer substrate adjacent to the second side of the die opposite of the first side of the die, such that the die is disposed between the substrate and the interposer substrate.
38. The method of clause 37, further comprising:
   coupling each of a plurality of vertical interconnects disposed outside the die in a horizontal direction, to a second metal trace among the one or more second metal traces; and
   coupling each of the plurality of vertical interconnects to the package substrate.
39. The method of clause 38, further comprising:
   forming one or more openings in a first outer surface of the insulating layer;
   disposing each of the one or more second metal traces in an opening among the one or more openings; and
   disposing each of the plurality of vertical interconnects at least partially in an opening among the one or more openings and coupled to a second metal trace among the one or more second metal traces in the opening.
40. The method of clause 37, further comprising forming one or more external interconnects each coupled to a second metal trace among the one or more second metal traces.
41. The method of clause 40, further comprising:
   forming one or more openings in a first outer surface of the insulating layer;
   disposing each of the one or more second metal traces in an opening among the one or more openings; and
   disposing each of the one or more external interconnects at least partially in an opening among the one or more openings and coupled to a second metal trace among the one or more second metal traces in the opening.
42. The method of clause 40 or 41, further comprising:
   coupling each of a plurality of vertical interconnects disposed outside the die in a horizontal direction to the second metal trace among the one or more second metal traces; and
   coupling each of the plurality of vertical interconnects to the package substrate.

What is claimed is:

1. An integrated circuit (IC) package, comprising:
a substrate comprising a first metallization layer, comprising:
an insulating layer comprising a first surface; and
a metal layer comprising a plurality of metal traces embedded in the insulating layer; and
wherein:
one or more first metal traces among the plurality of metal traces, the one or more first metal traces each having a first thickness in a vertical direction; and
one or more second metal traces among the plurality of metal traces, the one or more second metal traces each having a second thickness less than the first thickness in the vertical direction.

2. The IC package of claim 1, wherein:
the one or more second metal traces among the plurality of metal traces each comprise a second metal surface recessed a second distance from a first outer surface of the insulating layer.

3. The IC package of claim 2, wherein:
the one or more first metal traces among the plurality of metal traces each comprise a second metal surface recessed a first distance greater than the second distance from the first outer surface of the insulating layer.

4. The IC package of claim 1, wherein:
the one or more first metal traces among the plurality of metal traces each comprise a first metal surface extending to a first outer surface of the insulating layer; and
the one or more second metal traces among the plurality of metal traces each comprise a second metal surface recessed from the first outer surface of the insulating layer.

5. The IC package of claim 1, further comprising one or more openings in the first surface of the insulating layer;
wherein the one or more second metal traces are each disposed in an opening among the one or more openings below the first surface of the insulating layer.

6. The IC package of claim 1, wherein the substrate does not comprise a solder resist layer adjacent to the first metallization layer.

7. The IC package of claim 1, further comprising one or more interconnects each coupled to a second metal trace among the one or more second metal traces;
wherein the one or more interconnects are each direct metal bonded to a second metal trace among the one or more second metal traces.

8. The IC package of claim 1, further comprising one or more interconnects each coupled to a second metal trace among the one or more second metal traces; and
further not comprising a solder joint coupling any of the one or more interconnects to the second metal trace among the one or more second metal traces.

9. The IC package of claim 1, wherein the substrate comprises a second metallization layer, and further comprising:
a die coupled to the second metallization layer; and
one or more external interconnects each coupled to a second metal trace among the one or more second metal traces.

10. The IC package of claim 9, further comprising one or more openings in the first surface of the insulating layer;
the one or more second metal traces each disposed in an opening among the one or more openings; and
the one or more external interconnects are each at least partially disposed in an opening among the one or more openings and coupled to the second metal trace among the one or more second metal traces in the opening.

11. The IC package of claim 9, wherein:
the die comprises a first side and a second side opposite the first side; and
the first side of the die is coupled to the second metallization layer of the substrate; and
further comprising an interposer substrate adjacent to the second side of the die, such that the die is disposed between the substrate and the interposer substrate.

12. The IC package of claim 11, further comprising a plurality of vertical interconnects disposed outside the die in a horizontal direction, wherein:
the interposer substrate comprises a third metallization layer comprising a plurality of third metal interconnects; and
each vertical interconnect among the plurality of vertical interconnects couples a third metal interconnect among the plurality of third metal interconnects, to a second metal interconnect among a plurality of second metal interconnects.

13. The IC package of claim 1, further comprising:
a die comprising a first side and a second side opposite the first side,
the first side of the die is coupled to the first metallization layer of the substrate; and
an interposer substrate adjacent to the second side of the die, such that the die is disposed between the substrate and the interposer substrate; and
a plurality of vertical interconnects disposed outside the die in a horizontal direction, wherein:
the interposer substrate comprises a third metallization layer comprising a plurality of third metal interconnects; and
each vertical interconnect among the plurality of vertical interconnects couples a third metal interconnect among the plurality of third metal interconnects in the third metallization layer of the interposer substrate, to a second metal trace among the one or more second metal traces.

14. The IC package of claim 13, further comprising a plurality of die interconnects each coupled to the first side of the die and each coupled to a first metal trace among the one or more first metal traces.

15. The IC package of claim 14, further comprising one or more openings in a first outer surface of the insulating layer;
the one or more second metal traces each disposed in an opening among the one or more openings; and
the plurality of vertical interconnects are each at least partially disposed in an opening among the one or more openings and are each coupled to a second metal trace among the one or more second metal traces in the opening.

16. The IC package of claim 1, further comprising:
a package substrate; and
a die comprising a first side and a second side opposite the first side, wherein the first side of the die is coupled to the package substrate;
wherein the substrate comprises an interposer substrate adjacent to the second side of the die, such that the die is disposed between the substrate and the interposer substrate.

17. The IC package of claim 16, further comprising a plurality of vertical interconnects disposed outside the die in a horizontal direction,
wherein each vertical interconnect among the plurality of vertical interconnects couples to a second metal trace among the one or more second metal traces, to the package substrate.

18. The IC package of claim 17, further comprising one or more openings in the first surface of the insulating layer;
the one or more second metal traces each disposed in an opening among the one or more openings; and
the plurality of vertical interconnects each at least partially disposed in an opening among the one or more openings and coupled to a second metal trace among the one or more second metal traces in the opening.

19. The IC package of claim 16, further comprising one or more external interconnects each coupled to a second metal trace among the one or more second metal traces.

20. The IC package of claim 19, further comprising one or more openings in a first outer surface of the insulating layer;
the one or more second metal traces each disposed in an opening among the one or more openings; and
the one or more external interconnects are each at least partially disposed in an opening among the one or more openings and coupled to a second metal trace among the one or more second metal traces in the opening.

21. The IC package of claim 19, further comprising a plurality of vertical interconnects disposed outside the die in a horizontal direction,
wherein each vertical interconnect among the plurality of vertical interconnects couples a second metal trace among the one or more second metal traces, to the package substrate.

22. The IC package of claim 1, further comprising:
a first die comprising a first side and a second side opposite the first side, wherein the first side of the first die is coupled to the substrate;
an interposer substrate adjacent to the second side of the first die, such that the first die is disposed between the substrate and the interposer substrate; and
a second die coupled to the interposer substrate such that the interposer substrate is disposed between the first die and the second die.

23. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

24. A method of fabricating a substrate for an integrated circuit (IC) package, comprising:
forming a substrate comprising forming a first metallization layer, comprising:
forming an insulating layer comprising a first surface; and
forming a metal layer comprising a plurality of metal traces in the insulating layer, comprising:
embedding one or more first metal traces among a plurality of metal traces, the one or more first metal traces each having a first thickness in a vertical direction; and
embedding one or more second metal traces among the plurality of metal traces, the one or more second metal traces each having a second thickness less than the first thickness in the vertical direction.

25. The method of claim 24, further comprising:
forming one or more openings in a first outer surface of the insulating layer; and
disposing each of the one or more second metal traces in an opening among the one or more openings below the first surface of the insulating layer.

26. The method of claim 24, further comprising not forming a solder resist layer adjacent to the first metallization layer.

27. The method of claim 24, further comprising:
forming one or more interconnects each coupled to a second metal trace among the one or more second metal traces; and
metal bonding each of the one or more interconnects to the second metal trace among the one or more second metal traces.

28. The method of claim 24, further not comprising a solder joint coupling any of the one or more interconnects, to a second metal trace among the one or more second metal traces.

29. The method of claim 24, further comprising:
coupling a first side of a first die to the substrate;
disposing an interposer substrate adjacent to a second side of the first die opposite the first side of the first die, such that the first die is disposed between the substrate and the interposer substrate; and
coupling a second die to the interposer substrate, such that the interposer substrate is disposed between the first die and the second die.

30. The method of claim 24, further comprising:
coupling a die coupled to a second metallization layer in the substrate; and
coupling one or more external interconnects to a second metal trace among the one or more second metal traces.

31. The method of claim 30, further comprising:
forming one or more openings in a first outer surface of the insulating layer;
disposing each of the one or more second metal traces in an opening among the one or more openings; and
disposing each of the one or more external interconnects at least partially in an opening among the one or more openings and coupling to the second metal trace among the one or more second metal traces in the opening.

32. The method of claim 30, further comprising:
coupling a first side of a first die to the second metallization layer of the substrate; and
disposing an interposer substrate adjacent to a second side of the die opposite the first side of the die, such that the die is disposed between the substrate and the interposer substrate.

33. The method of claim 32, further comprising:
coupling each of a plurality of vertical interconnects disposed outside the die in a horizontal direction to a metal interconnect among a plurality of metal interconnects in a third metallization layer of the interposer substrate; and
coupling each of the plurality of vertical interconnects to a second metal interconnect among a plurality of second metal interconnects in the second metallization layer of the substrate.

34. The method of claim 24, further comprising:
coupling a first side of a first die to the first metallization layer of the substrate;
disposing an interposer substrate adjacent to a second side of the first die opposite the first side of the first die, such that the first die is disposed between the substrate and the interposer substrate; and
coupling a plurality of vertical interconnects disposed outside the first die in a horizontal direction, each of the plurality of vertical interconnects coupling a metal interconnect among the plurality of metal interconnects in a third metallization layer of an interposer substrate, to a second metal trace among the one or more second metal traces.

35. The method of claim 34, further comprising coupling each of a plurality of die interconnects to the first side of the die and to a first metal trace among the one or more first metal traces.

36. The method of claim 35, further comprising:
forming one or more openings in a first outer surface of the insulating layer;
disposing each of the one or more second metal traces in an opening among the one or more openings; and
disposing each of the plurality of vertical interconnects at least partially in an opening among the one or more openings and coupling to the second metal trace among the one or more second metal traces in the opening.

37. The method of claim 24, further comprising:
providing a package substrate;
coupling a first side of a die to the package substrate; and
disposing the substrate comprises an interposer substrate adjacent to the second side of the die opposite of the first side of the die, such that the die is disposed between the substrate and the interposer substrate.

38. The method of claim 37, further comprising:
coupling each of a plurality of vertical interconnects disposed outside the die in a horizontal direction, to a second metal trace among the one or more second metal traces; and
coupling each of the plurality of vertical interconnects to the package substrate.

39. The method of claim 38, further comprising:
forming one or more openings in a first outer surface of the insulating layer;
disposing each of the one or more second metal traces in an opening among the one or more openings; and
disposing each of the plurality of vertical interconnects at least partially in an opening among the one or more openings and coupled to a second metal trace among the one or more second metal traces in the opening.

40. The method of claim 37, further comprising forming one or more external interconnects each coupled to a second metal trace among the one or more second metal traces.

41. The method of claim 40, further comprising:
forming one or more openings in a first outer surface of the insulating layer;
disposing each of the one or more second metal traces in an opening among the one or more openings; and
disposing each of the one or more external interconnects at least partially in an opening among the one or more openings and coupled to a second metal trace among the one or more second metal traces in the opening.

42. The method of claim 40, further comprising:
coupling each of a plurality of vertical interconnects disposed outside the die in a horizontal direction to the second metal trace among the one or more second metal traces; and
coupling each of the plurality of vertical interconnects to the package substrate.
